(19) United States
(12) Patent Application Publication
(10) Pub. No.: US 2018/0108583 A1
(43) Pub. Date: Apr. 19, 2018

(54) DEVICE CHIP, ACCOMMODATING TRAY, AND METHOD OF ACCOMMODATING DEVICE CHIPS

(71) Applicant: DISCO CORPORATION, Tokyo (JP)

(72) Inventor: Koichi Kondo, Tokyo (JP)

(21) Appl. No.: 15/730,971

(22) Filed: Oct. 12, 2017

(30) Foreign Application Priority Data
Oct. 14, 2016 (JP) 2016-203069

(51) Int. Cl. H01L 23/13; H01L 21/673; H01L 21/677

(52) U.S. Cl. CPC H01L 23/13; H01L 2924/143; H01L 21/67793; H01L 21/67333

(57) ABSTRACT

A device chip is shaped as an inverted frustum with a device formed on an upper surface thereof. An accommodating tray for accommodating a plurality of device chips each shaped as an inverted frustum with a device formed on an upper surface thereof, has a plurality of open recesses defined in an upper surface thereof, for accommodating device chips therein, each of the recesses having a bottom surface and a side surface which form an obtuse angle therebetween. A method of accommodating the device chips in the accommodating tray includes a supplying step of supplying the device chips onto the accommodating tray, and after the device chips supplying step is performed, an accommodating step of imparting vibrations to the accommodating tray to cause the device chips into the recesses thereby placing the device chips in the recesses.

### BACKGROUND OF THE INVENTION

### Field of the Invention

The present invention relates to a device chip and an accommodating tray for accommodating device chips. The present invention is also concerned with a method of accommodating device chips.

### Description of the Related Art

Chips having devices such as integrated circuits (ICs), large-scale integration (LSI) circuits, etc. thereon (hereinafter referred to as “device chips”) are fabricated from a wafer which is substantially disk-shaped with a plurality of devices formed on its face side when the wafer is divided into such device chips. The devices are formed in respective areas demarcated on the face side of the wafer by a grid of projected dicing lines. Device chips are installed in various electronic devices such as mobile phones, personal computers, etc. and are widely used in the art. There are growing demands for various smaller electronic devices and hence for smaller device chips, with the result that device chips having a size of not more than 1 mm on each side, for example, has been manufactured. Individual device chips divided from wafers are accommodated in accommodating trays for transport, etc. Japanese Patent Laid-open No. 2006-156777 discloses a technology wherein fabricated device chips are picked up and accommodated into an accommodating tray.

### SUMMARY OF THE INVENTION

Providing the size of device chips is reduced, the number of device chips fabricated from one wafer is increased. The time required by a process of picking up fabricated device chips one by one and accommodating them into an accommodating tray is also increased. In addition, a collet on a picker that is used to pick up device chips needs to be of a reduced size commensurate with the size of the device chips. However, it is not easy to form a collet in a manner to match the size of device chips that have a size of not more than 1 mm on each side, for example.

It is therefore an object of the present invention to provide a device chip that can easily be accommodated into an accommodating tray and an accommodating tray that is capable of easily accommodating device chips therein. It is also an object of the present invention to provide a method of efficiently accommodating device chips into an accommodating tray.

In accordance with an aspect of the present invention, there is provided a device chip shaped as an inverted frustum with a device formed on an upper surface thereof.

According to another aspect of the present invention, there is also provided an accommodating tray for accommodating a plurality of device chips each shaped as an inverted frustum with a device formed on an upper surface thereof, wherein the accommodating tray has a plurality of open recesses defined in an upper surface thereof, for accommodating device chips therein, each of the recesses having a bottom surface and a side surface which form an obtuse angle therebetween.

According to still another aspect of the present invention, there is further provided a method of accommodating a plurality of device chips each shaped as an inverted frustum with a device formed on an upper surface thereof, in an accommodating tray a plurality of open recesses defined in an upper surface thereof, each of the recesses having a bottom surface and a side surface which form an obtuse angle therebetween, the method including a supplying step of supplying the device chips onto the accommodating tray, after the device chips supplying step is performed, an accommodating step of imparting vibrations to the accommodating tray to cause the device chips into the recesses thereby placing the device chips in the recesses.

According to the aspect of the present invention, the device chip is shaped as an inverted frustum, rather than a rectangular parallelepiped. According to the other aspect of the present invention, the angle formed between the bottom surface and the side surface of each of the recesses in the accommodating tray is an obtuse angle, and the recesses are shaped complementarily to the device chips. According to the still other aspect of the present invention, when the device chips are supplied onto the accommodating tray and then the accommodating tray is vibrated, the device chips fall into the recesses and are placed in the recesses. If a device comes over a recess when the upper surface of the device on which the device is formed is oriented in any of directions other than an upward direction, the device does not fall into the recess because their shapes interfere with other, but is repelled by the vibrating accommodating tray. The device chips can be accommodated in the accommodating tray while being oriented in a particular direction because of the matching shapes of the recesses and the device chips. According to a conventional accommodating method, the device chips need to be picked up one by one and oriented in a particular direction, in addition to being carried to the accommodating tray. Therefore, the conventional accommodating method is time-consuming and tedious to carry out. With the accommodating method according to the present invention, the device chips are accommodated altogether in the accommodating tray while being oriented in a particular direction.

According to the aspects of the present invention, as described above, the device chip can easily be accommodated in the accommodating tray, and the accommodating tray is capable of easily accommodating the device chips therein. Furthermore, the method is capable of accommodating the device chips efficiently into the accommodating tray.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view depicting an example of a device chip;

FIG. 1B is a perspective view depicting another example of a device chip;

FIG. 10 is a cross-sectional view schematically depicting an accommodating tray;

FIG. 2A is a perspective view schematically illustrating a device chip supply step; and

FIG. 2B is a cross-sectional view schematically illustrating an accommodating step.

### DETAILED DESCRIPTION OF THE PREFERRED EMBODIMENT

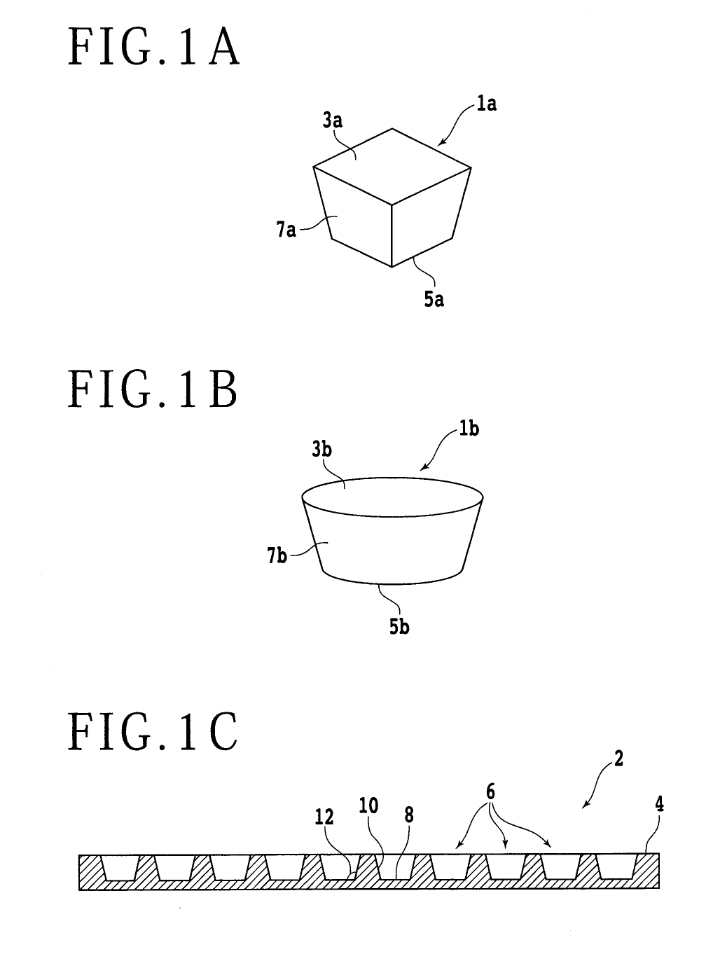

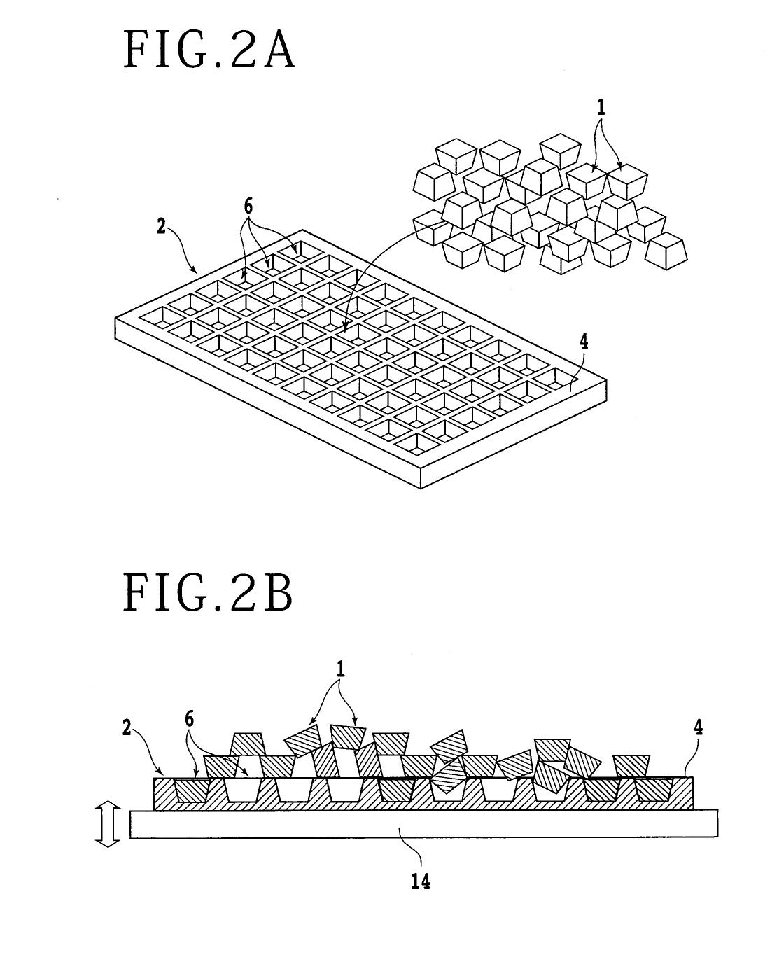

An embodiment of the present invention will be described below. A device chip according to the present invention is shaped as an inverted frustum. The inverted frustum used herein refers to a three-dimensional shape representing an inverted three-dimensional frustum as the wider part of a cone or pyramid, including its base, that remains after its pointed part is cut off by a plane parallel to the base. The inverted frustum has upper and lower surfaces parallel to each other, the upper surface being larger than the lower surface. The angle formed between the upper surface and the side surfaces is an acute angle, and the angle formed between the lower surface and the side surfaces is an obtuse angle. FIG. 1A depicts in perspective a device chip 1a shaped as an inverted square frustum or inverted truncated square pyramid with a device formed on an upper surface 3a thereof. The area of the upper surface 3a is larger than the area of a lower surface 5a of the inverted square frustum, and four side surfaces 7a lying between the upper surface 3a and the lower surface 5a have sides near the upper surface 3a which are longer than sides thereof near the lower surface 5a. FIG. 1B depicts in perspective a device chip 1b shaped as an inverted circular frustum or inverted truncated cone with a device formed on an upper surface 3b thereof. The area of the upper surface 3b is larger than the area of a lower surface 5b of the inverted circular frustum, and a side surface 7b lying between the upper surface 3b and the lower surface 5b has a side near the upper surface 3b which is longer than a side thereof near the lower surface 5b. The device chip according to the present invention is not limited to the shape of an inverted square or circular frustum, but may be shaped as an inverted hexagonal frustum, for example. When the device chips 1a and 1b do not need to be distinguished from each other, i.e., when they are to be addressed without regard for their shapes, the device chips will be referred to as device chips 1.

A device such as an IC, an LSI circuit, or the like is formed on the upper surface of the device chip. Device chips are fabricated, for example, from a substantially disk-shaped wafer with a plurality of devices formed on its face side in respective areas demarcated by a grid of projected dicing lines when the wafer is divided along the projected dicing lines into such device chips.

The wafer can be divided into device chips by a rotating disk-shaped cutting blade that cuts into the reverse side of the wafer and is displaced along the projected dicing lines, for example. If the cutting blade is inclined to a direction perpendicular to the plane of the wafer, then surfaces of the wafer formed by the cutting blade are also inclined to a direction perpendicular to the face and reverse sides of the wafer. For example, the cutting blade to be displaced along a projected dicing line is inclined such that its upper end is closer to one of two areas demarcated by the projected dicing line, and the wafer is cut from the reverse side by the inclined cutting blade along the projected dicing line. Thereafter, the cutting blade is inclined such that its upper end is closer to the other of the two areas and displaced toward the other area, and the wafer is cut from the reverse side by the inclined cutting blade along the same projected dicing line. When the wafer is thus cut twice along each projected dicing line by the cutting blade that is inclined in different directions for the respective cutting sessions, the wafer can be divided into individual device chips each having the shape of an inverted square frustum.

Alternatively, a cylindrical, conical, or frustoconical resist is provided on the reverse side of the wafer over each of the areas demarcated by the projected dicing lines, and the wafer is processed by anisotropic etching from the reverse side thereof to fabricate individual device chips each having the shape of an inverted circular frustum. If the resist provided on the reverse side of the wafer over each of the areas demarcated by the projected dicing lines is shaped as a square prism, a square pyramid, or a square frustum, then device chips each having the shape of an inverted square frustum can be fabricated from the wafer. The resist includes a resist that is retracted or reduced by anisotropic etching. Specifically, anisotropic etching is started to etch the portion of the wafer that is not covered by the resist, while at the same time the resist is gradually retracted or reduced by anisotropic etching. The portion of the wafer that is concealed by the resist is thus gradually narrowed, and the region of the wafer which is to be newly etched is gradually widened. The etching process thus performed turns the portion of the wafer that remains unremoved into a device chip shaped as an inverted frustum. Different resist shapes result in device chips having different inverted frustum shapes.

The wafer includes a substantially disk-shaped wafer made of a material such as silicon, sapphire, or the like, or a circular substrate made of glass, quartz, or the like. If the wafer is made of a semiconductor material, devices are formed thereon using part of the material of the wafer. If the wafer is not made of a semiconductor material, then a semiconductor layer is deposited on the face side of the wafer and devices are formed on the wafer by processing the semiconductor layer.

An accommodating tray according to the present embodiment will be described below. FIG. 1C schematically depicts in cross section an accommodating tray 2 according to the present embodiment. As depicted in FIG. 1C, the accommodating tray 2 has a plurality of open recesses 6 defined in an upper surface 4 for accommodating device chips 1 therein. Each of the recesses 6 has a bottom surface 8 and side surfaces 10, and the angle formed between the bottom surface 8 and the side surfaces 8 is an obtuse angle. This shape of the recesses 6 is complementary to the shape of the device chips 1. In other words, each of the recesses 6 is a hole shaped as an inverted frustum. If the accommodating tray 2 is to accommodate device chips each shaped as an inverted circular frustum, then the recesses 6 in the accommodating tray 2 are holes shaped as an inverted circular frustum each. If the accommodating tray 2 is to accommodate device chips each shaped as an inverted square frustum, then the recesses 6 in the accommodating tray 2 are holes shaped as an inverted square frustum each. The accommodating tray 2 is fabricated by molding a flowable resin material to a predetermined shape and letting it solidify. The recesses 6 in the accommodating tray 2 are formed by pouring a flowing resin material onto a mold that has a plurality of bosses on a flat plate each shaped as a frustum complementarily to the recesses 6. When the resin material solidifies, it becomes the accommodating tray 2 with the recesses 6 defined therein. The recesses 6 may alternatively be formed by cutting a thick resin plate to a predetermined shape.

As described above, the device chips 1 with the devices formed thereon are shaped as an inverted frustum, and the recesses 6 in the accommodating tray 2 are shaped complementarily to the device chips 1 shaped as an inverted frustum. When the device chips 1 are placed onto the accommodating tray 2, they are accommodated therein with the lower surfaces of the device chips 1 facing the bottoms of the recesses 6 and the upper surfaces of the device chips 1 facing upwardly. If an attempt is made to try accommodating the device chips 1 in other orientations into the accommodating tray 2, the device chips 1 cannot be put in the recesses 6 as they interfere with each other. In other words, the orientations of the device chips 1 are appropriately controlled to accommodate the device chips 1 in the accommodating tray 2. When device chips are accommodated in an accommodating tray and transported, the orientations of the device chips may be required to be aligned with a certain direction and accommodated in the accommodating tray in order to allow the device chips to be handled with ease at the site which the device chips are transported to. The accommodating tray 2 according to the present embodiment is able to accommodate the device chips 1 while they are being oriented only in a particular direction. Even if the device chips 1 are not picked up one by one and controlled in their orientation and then accommodated, the device chips 1 can be accommodated in the accommodating tray 2 while being oriented in a particular direction according to an accommodating method to be described below.

An accommodating method according to the present embodiment for accommodating the device chips 1 into the accommodating tray 2 will be described below with reference to FIGS. 2A and 2B. In the accommodating method according to the present embodiment, a device chip supply step is first carried out to supply the device chips 1 onto the accommodating tray 2. FIG. 2A schematically illustrates the device chip supply step in perspective. In the device chip supply step, as depicted in FIG. 2A, the device chips 1 are supplied onto the accommodating tray 2 with the open recesses 6 defined in the upper surface 2a thereof. At this time, the device chips 1 does not need to be picked up one by one, but may be supplied altogether onto the accommodating tray 2, as depicted in FIG. 2A.

The device chip supply step is followed by an accommodating step. In the accommodating step, the accommodating tray 2 is vibrated to cause each of the device chips 1 into either one of the recesses 6 until the device chips 1 are placed into the recesses 6. FIG. 2B schematically illustrates the accommodating step in cross section. In FIG. 2B, the device chips 1 are cross-sectionally depicted as being of the same size and shape. Actually, however, when the device chips 1 before they are put into the recesses 6 are cut along one plane, the cross-sectional sizes and shapes of the device chips 1 cut along the plane may not be viewed as depicted in FIG. 2B.

First, the accommodating tray 2 with the device chips 1 supplied thereto is placed on a vibrating base 14. Then, the vibrating base 14 is actuated to vibrate and transmit its vibrations to the accommodating tray 2. The device chips 1 on the accommodating tray 2 are repelled by the vibrating accommodating tray 2 and moved on the accommodating tray 2 while changing their orientations. If the orientation of a device chip 1 that happens to come over a recess 6 does not match the shape of the recess 6, then the device chip 1 is not fully placed in the recess 6 though it may partly enter the recess 6. The device chip 1 is then caused to jump out of the recess 6 by the vibrations and move over the accommodating tray 2 while changing their orientation at random again. On the other hand, if the orientation of a device chip 1 that happens to come over a recess 6 matches the shape of the recess 6, then the device chip 1 falls into the recess 6 and is placed in the recess 6. Once fully received in the recess 6, it remains snugly trapped in the recess 6 unless strongly repelled by the vibration until it jumps over the side surfaces of the recess 6. The intensity of the vibrations of the vibrating base 14 is set to such a value as not to eject the device chip 1 out of the recess 6 in which it has been neatly fit.

As the vibrating base 14 continues to vibrate, all the device chips 1 supplied to the accommodating tray 2 are eventually placed in the respective recesses 6. However, if the process of placing the device chips 1 into the recesses 6 is slowed down because the number of empty recesses 6 is reduced, the vibrating base 14 is disabled to stop its vibrations, and the operator manually tilts the accommodating tray 2 to guide the device chips 1 that remain to be settled in toward the empty recesses 6, after which the operator resumes vibrating the accommodating tray 2. Not all the recesses 6 in the accommodating tray 2 may be filled with the device chips 1. When the number of empty recesses 6 is reduced to the extent that the efficiency of the process of placing the device chips 1 into the recesses 6 becomes too low, the operator may remove the remaining device chips 1 from the accommodating tray 2 by tipping the accommodating tray 2. The removed device chips 1 may be supplied onto another accommodating tray 2.

With the accommodating method according to the present embodiment, the device chips 1 can be accommodated in the accommodating tray 2 while being oriented altogether in a particular direction because of the matching shapes of the recesses 6 in the accommodating tray 2 and the device chips 1. Therefore, the efficiency of the process of placing the device chips 1 into the recesses 6 is very high. The present invention is not limited to the illustrated embodiment, but various changes and modifications may be made in the embodiment. For example, although the devices are formed on the upper surfaces of the device chips 1 in the above embodiment, the devices may be formed on the lower surfaces of the device chips 1 each shaped as an inverted frustum. According to such a modification, since the surfaces of the device chips 1 on which the devices are formed are not exposed when the device chips 1 are accommodated in the accommodating tray 2, the devices on the device chips 1 are protected more reliably while the accommodating tray 2 with the device chips 1 accommodated therein is being transported.

The structural details, processes and methods, and other details of the above embodiment may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A device chip shaped as an inverted frustum with a device formed on an upper surface thereof.

2. An accommodating tray for accommodating a plurality of device chips each shaped as an inverted frustum with a device formed on an upper surface thereof, wherein
said accommodating tray has a plurality of open recesses defined in an upper surface thereof, for accommodating device chips therein, each of said recesses having a bottom surface and a side surface which form an obtuse angle therebetween.

3. A method of accommodating a plurality of device chips each shaped as an inverted frustum with a device formed on an upper surface thereof, in an accommodating tray a plurality of open recesses defined in an upper surface thereof, each of said recesses having a bottom surface and a side surface which form an obtuse angle therebetween, said method comprising:
a supplying step of supplying the device chips onto the accommodating tray; and
after the device chips supplying step is performed, an accommodating step of imparting vibrations to the accommodating tray to cause the device chips into the recesses thereby placing the device chips in the recesses.
